(19) United States
(12) Patent Application Publication
(10) Pub. No.: US 2025/0076090 A1
(43) Pub. Date: Mar. 6, 2025

(54) OPTIMIZED MULTI-PATH LOOP SYSTEM FOR CONDITION CHANGE DETECTION

(71) Applicant: Temptime Corporation, Morris Plains, NJ (US)

(72) Inventors: Eric LIBERATO, Pequannock, NJ (US); Mohannad ABDO, Clifton, NJ (US); Ashley COUSIN, Chatham, NJ (US)

(73) Assignee: Temptime Corporation, Morris Plains, NJ (US)

(21) Appl. No.: 18/240,153

(22) Filed: Aug. 30, 2023

(51) Int. Cl. G01D 21/00

(52) U.S. Cl. CPC G01D 21/00

(57) ABSTRACT

Systems and methods of an optimized multi-path loop system for condition change detection are provided. An example includes a system comprising a multi-path loop component, the multi-path loop component including a plurality of interleaved discontinuous conductive paths that form a parallel circuit component, and a logic circuit operatively coupled to the multi-path loop component. The logic circuit may be configured to detect whether a continuous circuit path has been formed by at least one of the plurality of interleaved discontinuous conductive paths in response to at least one environmental condition in an area defined by the plurality of interleaved discontinuous conductive paths. The logic circuit may also be configured to output a signal that indicates that formation of the continuous circuit path has been detected.

### BACKGROUND

Tamper evident loops can be used to detect a binary condition with one state being represented by a closed loop and the other state by an open loop. These loops generally are formed with a single conductive path that when broken indicates evidence of tampering, which may be suitable for many applications. However, this can limit the range or applicability of the loop, particularly where the loop is implemented as part of an environmental monitoring circuit. Accordingly, there is a need for alternatives that overcome these challenges.

### SUMMARY

Systems and methods for an optimized multi-path loop system for condition change detection are provided. In an embodiment, the present disclosure includes a system comprising a multi-path loop component. The multi-path loop component includes a plurality of interleaved discontinuous conductive paths that form a parallel circuit component. The system also includes a logic circuit operatively coupled to the multi-path loop component. The logic circuit may be configured to detect whether a continuous circuit path has been formed by at least one of the plurality of interleaved discontinuous conductive paths in response to at least one environmental condition in an area defined by the plurality of interleaved discontinuous conductive paths. The logic circuit may also be configured to output a signal that indicates that formation of the continuous circuit path has been detected.

In a variation of this embodiment, the system may further comprise an antenna, and the logic circuit may be configured to output the signal via the antenna in response to detecting that the continuous circuit path has been formed.

In another variation of this embodiment, the system may further comprise an antenna, and the logic circuit may be configured to output the signal via the antenna in response to receipt of a radiofrequency communication via the antenna after detecting that the continuous circuit path has been formed.

In another variation of this embodiment, the area defined by the plurality of interleaved discontinuous paths has a perimeter with a circular, oval, or rectangular shape.

In another variation of this embodiment, discontinuities of adjacent ones of the plurality of interleaved discontinuous paths are at least partially offset from each other.

In another variation of this embodiment, the system may further comprise a substrate, and the multi-path loop component is formed from at least one metallic etching etched into the substrate or transfer of an electrically conductive ink onto the substrate.

In another variation of this embodiment, the system may further comprise a reactive component that reacts to the at least one environmental condition, the reactive component including a conductive material disposed proximate to the area defined by the plurality of interleaved discontinuous conductive paths. The conductive material may be spaced away from the plurality of interleaved discontinuous conductive paths prior to the at least one environment condition, and the reactive component may react to the at least one environment condition may cause the conductive material to contact at least a portion of the area to form the continuous circuit path at least one of during or after the at least one environmental condition.

In a variation of this embodiment, the reactive component includes a meltable component that separates the conductive material from the plurality of interleaved discontinuous conductive paths, and the meltable component melts in response to the at least one environment condition.

In another variation of this embodiment, the at least one environmental condition includes at least one of a temperature that satisfies a temperature threshold, a humidity that satisfies a humidity threshold, a pressure that satisfies a pressure threshold, a mechanical property that satisfies a mechanical property threshold, exposure to a specified level of a chemical, or light that satisfies an illumination threshold.

In a variation of this embodiment, the environmental condition corresponds to the deposition of a conductive material onto the area of the plurality of interleaved discontinuous conductive paths in response to damage to or abnormal operation of an object being monitored by the logic circuit.

In a variation of this embodiment, the object is at least one of a battery, a pipe, hydraulic device, a pneumatic device, a motor, an engine, or a pump.

In another variation of this embodiment, at least one of the plurality of interleaved discontinuous conductive paths has at least two discontinuities.

In another variation of this embodiment, the logic circuit is further configured to detect formation of multiple continuous conductive paths in the plurality of interleaved discontinuous conductive paths, and is configured to output the signal after the multiple continuous conductive paths are formed.

In another variation of this embodiment, the logic circuit is configured to output the signal after continuous conductive paths are formed for each of the plurality of interleaved discontinuous conductive paths.

In another variation of this embodiment, a second multi-path loop is operatively coupled to the logic circuit in parallel or series with the multi-path loop.

In another variation of this embodiment, the system further comprises a second multi-path loop component and a second logic circuit, the second multi-path loop is operatively coupled to the second logic circuit.

In another embodiment, a method comprises in response to at least one environmental condition, detecting via a logic circuit whether a continuous circuit path has been formed by a multi-path loop component. The multi-path loop component includes a plurality of interleaved discontinuous conductive paths. Each interleaved discontinuous conductive path has at least one discontinuity. The plurality of interleaved discontinuous conductive paths form a parallel circuit component, wherein the logic circuit is operatively coupled to the multi-path loop component, and the method also includes outputting a signal via the logic circuit indicating that formation of the continuous circuit path has been detected.

In a variation of this embodiment, the method further comprises transmitting the output signal via an antenna.

In another variation of this embodiment, the method further comprises transmitting the output signal via an antenna, in response to receiving a radiofrequency communication via the antenna.

In another variation of this embodiment, the area defined by the plurality of interleaved discontinuous paths has a perimeter with a circular, oval, or rectangular shape.

In another variation of this embodiment, discontinuities of adjacent ones of the plurality of interleaved discontinuous paths are at least partially offset from each other.

In another embodiment, the multi-path loop component is formed from etching at least one metallic etching into a substrate or by transferring electrically conductive ink onto a substrate.

In a variation of this embodiment, detecting whether a continuous circuit path has been formed includes determining whether a reactive component has reacted to at least one environmental condition. The reactive component includes a conductive material disposed proximate to the area defined by the plurality of interleaved discontinuous conductive paths, and the conductive material is spaced away from the plurality of interleaved discontinuous conductive paths prior to the at least one environment condition, wherein the at least one environmental condition causes the conductive material to contact at least a portion of the area to form the continuous circuit path at least one of during or after the at least one environmental condition.

In another variation of this embodiment, the reactive component includes a meltable component that separates the conductive material from the plurality of interleaved discontinuous conductive paths, and the meltable component melts in response to the at least one environment condition.

In another variation of this embodiment, the at least one environmental condition includes at least one of a temperature that satisfies a temperature threshold, a humidity that satisfies a humidity threshold, a pressure that satisfies a pressure threshold, a mechanical property that satisfies a mechanical property threshold, exposure to a specified level of chemical, or light that satisfies an illumination threshold.

In another variation of this embodiment, the environmental condition corresponds to the deposition of a conductive material onto the area of the plurality of interleaved discontinuous conductive paths in response to damage to or abnormal operation of an object being monitored by the logic circuit.

In another variation of this embodiment, the object is at least one of a battery, a pipe, hydraulic device, a pneumatic device, a motor, an engine, or a pump.

In another variation of this embodiment, detecting via a logic circuit whether a continuous circuit path has been formed by a multi-path loop component includes detecting whether at least two discontinuities in each interleaved discontinuous conductive path have formed a continuous conductive path, in response to the at least one environmental condition.

In another variation of this embodiment, detecting via a logic circuit whether a continuous circuit path has been formed by a multi-path loop component includes detecting formation of multiple continuous conductive paths in the plurality of interleaved discontinuous conductive paths, and outputting a signal via the logic circuit indicating that formation of the multiple continuous circuit paths has been detected.

In another variation of this embodiment, detecting via the logic circuit whether a continuous circuit path has been formed by a multi-path loop component includes detecting formation of a continuous conductive path in a second multi-path loop operatively coupled to the logic circuit and in parallel or series with the multi-path loop component.

In another variation of this embodiment, detecting via a second logic circuit whether a continuous circuit path has been formed by a multi-path loop component includes detecting formation of a continuous conductive path in a second multi-path loop operatively coupled to the second logic circuit.

In another embodiment, the present disclosure includes a multi-path loop component, the multi-path loop component including a plurality of interleaved discontinuous conductive paths that form a parallel circuit component. Each of the interleaved discontinuous conductive paths has at least one discontinuity. The system additionally includes a reactive component that reacts to the at least one environmental condition. The reactive component includes a conductive material disposed in an area defined by the plurality of interleaved discontinuous conductive paths and is configured to connect the at least one discontinuity in each of the interleaved discontinuous conductive paths via the conductive material to provide continuous conductive paths. In response to the at least one environmental condition, the reactive component separates the conductive material from the continuous conductive paths to form discontinuous conductive paths. A logic circuit is operatively coupled to the multi-path loop component. The logic circuit is configured to detect whether a discontinuous path has been formed by at least one of the plurality of interleaved discontinuous conductive paths in response to at least one environmental condition in an area defined by the plurality of interleaved discontinuous conductive paths, and the logic circuit configured to output a signal that indicates that a discontinuity of the continuous circuit path has been detected.

In another embodiment, the present disclosure includes a method comprising in response to at least one environmental condition, detecting via a logic circuit whether a discontinuous circuit path has been formed by a multi-path loop component. The multi-path loop component includes a plurality of interleaved discontinuous conductive paths. Each interleaved discontinuous conductive path has at least one discontinuity. The plurality of interleaved discontinuous conductive paths form a parallel circuit component, wherein the logic circuit is operatively coupled to the multi-path loop component. A reactive component including a conductive material reacts to the at least one environmental condition. The reactive component is disposed in an area defined by the plurality of interleaved discontinuous conductive paths and is configured to complete the at least one discontinuity in each of the interleaved discontinuous conductive paths via the conductive material to provide continuous conductive paths. The method also includes outputting a signal via the logic circuit indicating that formation of a discontinuous circuit path has been detected.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIGS. 1A-C illustrate an example system of the present disclosure.

FIG. 2 illustrates an additional example system of the present disclosure.

FIGS. 3A-C illustrate an additional example system of the present disclosure in use over time.

FIGS. 4A-B illustrate an additional example system of the present disclosure.

FIGS. 5A-B illustrate an additional example system of the present disclosure.

FIG. 6 illustrates an additional example system of the present disclosure.

FIG. 7 is a flowchart illustrating an example method of the present disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

The system and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

### DETAILED DESCRIPTION

Embodiments of the present disclosure provide for an optimized multi-path loop system that includes a multi-path loop component for condition change detection and/or tamper detection. The multi-path loop component includes interleaved discontinuous conductive paths that form a parallel circuit component. A logic circuit can be operatively coupled to the multi-path loop component to detect whether a continuous circuit path has been formed by at least one of the interleaved discontinuous conductive paths in response to at least one environmental condition in an area defined by the plurality of interleaved discontinuous conductive paths and/or tampering. The logic circuit may also be configured to output a signal that indicates that formation of the continuous circuit path has been detected. The multi-path loop component advantageous allows for greater cover and surface area than convention solutions single path solutions and can be provide increased sensitivity such that a condition change and/or tampering causing at least one of the discontinuities over the are covered by the multi-path loop to be completed can result in a detection of condition change and/or tampering. Thus, the multi-path loop component can require can be useful in requiring less precision for manufacturing and to detect change conditions and/or tampering over a greater surface area. This can be particularly useful in applications where a precise location at which the condition change will be detected is unknown. The multi-path loop component can additional or in the alternative be used to register a change condition and/or tampering when some or all of the discontinuities are completed; thereby allowing greater customization and/or requiring multiple conditions to be met for the logic circuit can output a signal indicative of the change condition and/or tampering.

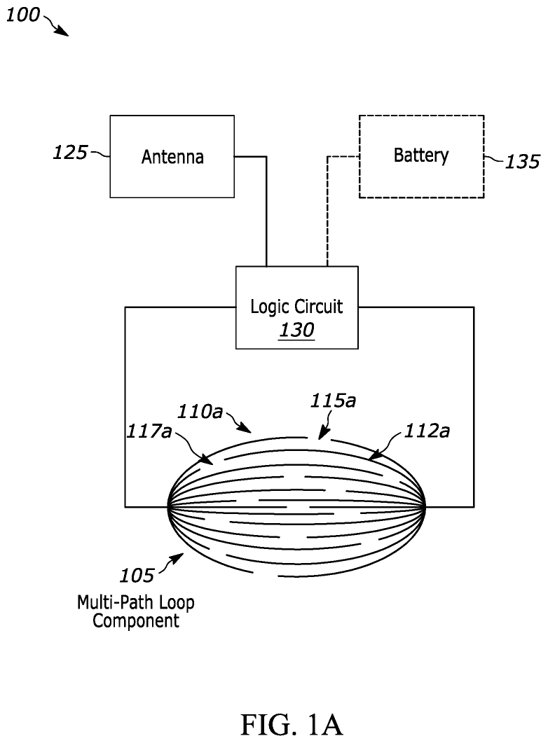

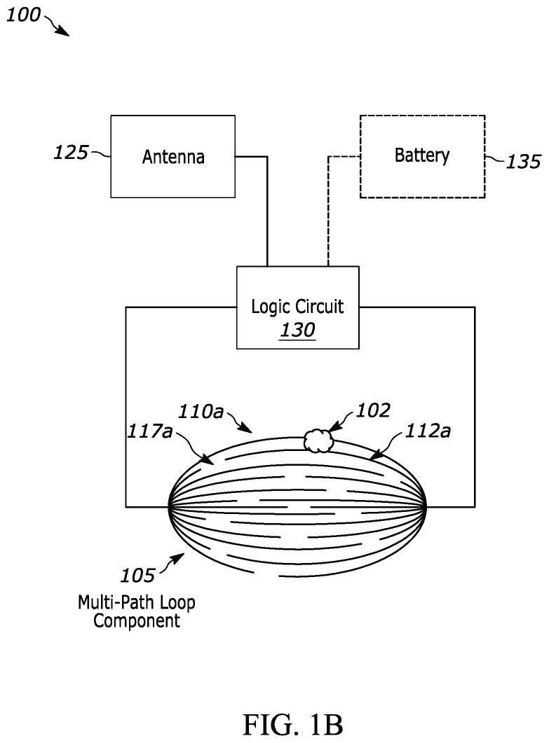

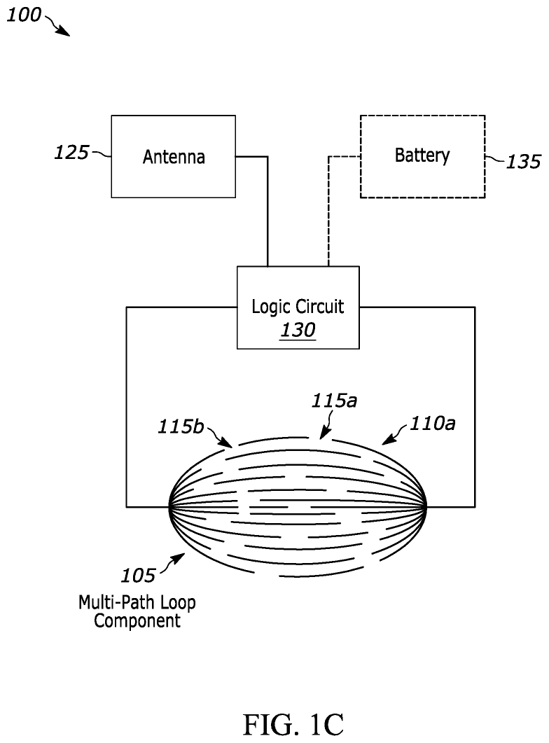

FIGS. 1A-C illustrate an example system 100 of the present disclosure. The system 100 may include a multi-path loop component 105 which includes a plurality of interleaved discontinuous conductive paths, such as path 110a, with each conductive path including at least one discontinuity, for example, discontinuity 115a. This plurality of interleaved discontinuous conductive paths forms a parallel circuit component, such that a continuous circuit path may be formed from any one of the conductive paths, for example by a conductive material bridging or completing discontinuity 115a to form a continuous conductive path 110a.

The multi-path loop component 105 may be formed by etching the interleaved discontinuous conductive paths printing or depositing electrically conductive ink to form the interleaved discontinuous conductive paths, for example an aluminized ink, on a substrate. One example of a material from which the substrate can be formed can be polyethylene terephthalate (PET). The plurality of interleaved discontinuous conductive paths of the multi-path loop component 105 may define an area with a perimeter which can have any suitable shape based on the application of the system. For example, the plurality of interleaved discontinuous conductive paths may define an area with a perimeter that has a circular, oval, or rectangular shape. For adjacent ones of the plurality of interleaved discontinuous paths, the discontinuities in each respective path may be at least partially offset from each other. For example, as shown in FIG. 1, discontinuous conductive paths 110a comprise discontinuity 115a, which is offset from discontinuity 117a in the adjacent discontinuous conductive path, path 112a. Additionally, or in the alternative, at least one of the plurality of interleaved discontinuous conductive paths of the multi-path loop component 105 can have at least two discontinuities (e.g., as shown in FIG. 1C).

The system 100 may also include a logic circuit 130 operatively connected to the multi-path loop component 105. The logic circuit 130 may be an integrated circuit or any other suitable circuitry. The logic circuit 130 may be configured to detect whether a continuous circuit path has been formed by at least one of the plurality of interleaved discontinuous conductive paths in response to at least one environmental condition in the area defined by the plurality of interleaved discontinuous conductive paths. The environmental condition may correspond to the deposition of a conductive material 102 onto the area of the plurality of interleaved discontinuous conductive paths in response to damage to or abnormal operation of an object being monitored by the logic circuit, at least one of a temperature that satisfies a temperature threshold, a humidity that satisfies a humidity threshold, a pressure that satisfies a pressure threshold, a mechanical property that satisfies a mechanical property threshold, exposure to a specified level of chemical, light that satisfies an illumination threshold, and/or other environmental conditions.

As one example, the system 100 may be configured to detect an environmental condition that corresponds to battery leakage, where the multi-path loop component 105 is affixed or otherwise in proximity to a battery. In the event of leakage from the battery, a conductive material (e.g., the battery fluid) leaking from the battery can come in contact with at least a portion of the area defined by the plurality of interleaved discontinuous conductive paths and the conductive material can complete at least one of the discontinuous conductive paths forming a continuous circuit between the terminal ends of the multi-path loop component 105, which can be detected by the logic circuit 130. In this way, logic circuit 130 may be configured to detect leakage by determining if a completed circuit path exists in the multi-path loop component 105.

As another example, the multi-path loop component 105 may be affixed or disposed in proximity to a pipe in order to detect leakage of a conductive material, e.g. water. The multi-path loop component 105 may be positioned such that when the pipe leaks, the fluid leaking from the pipe comes in contact with at least a portion of the area defined by the plurality of interleaved discontinuous conductive paths causing at least one of the discontinuous conductive paths to be completed to form a continuous circuit between the terminal ends of the multi-path loop component 105, which can be detected by the logic circuit 130. In response to determining that a continuous circuit path has been formed, the logic circuit 130 may output a signal. The logic circuit 130 may also be configured to monitor other objects, for example, a hydraulic device, a pneumatic device, a motor, an engine, a pump, and/or other objects which may discharge conductive material.

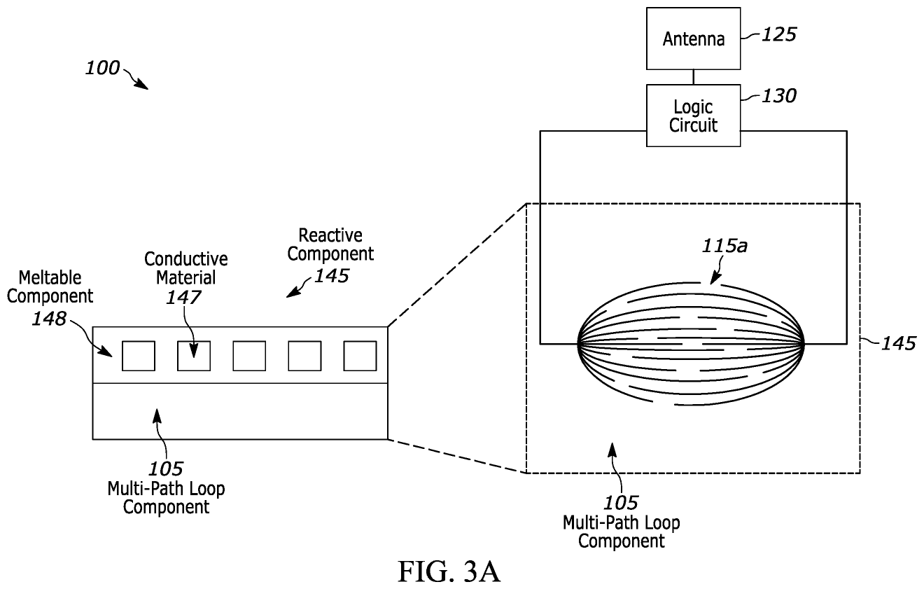

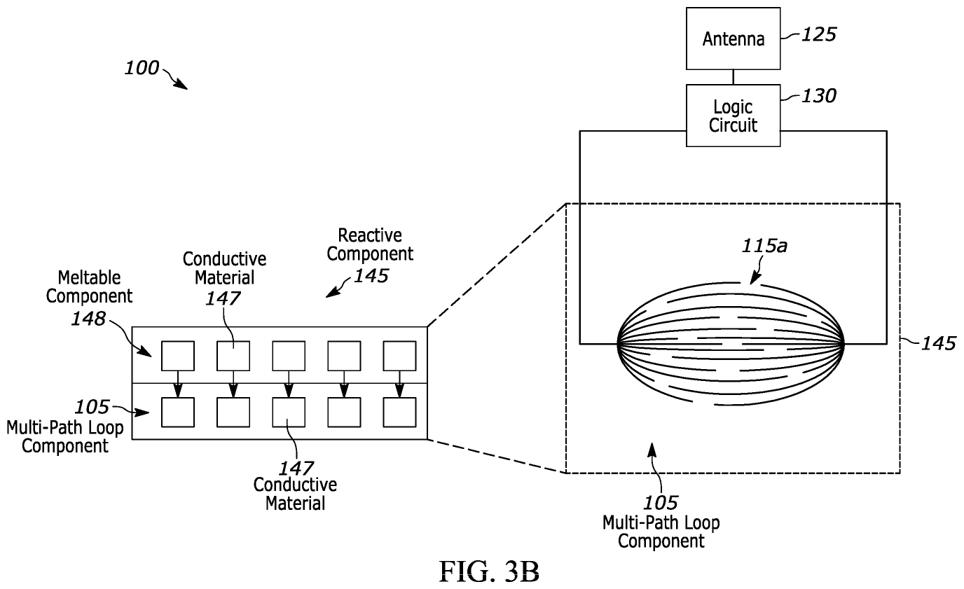

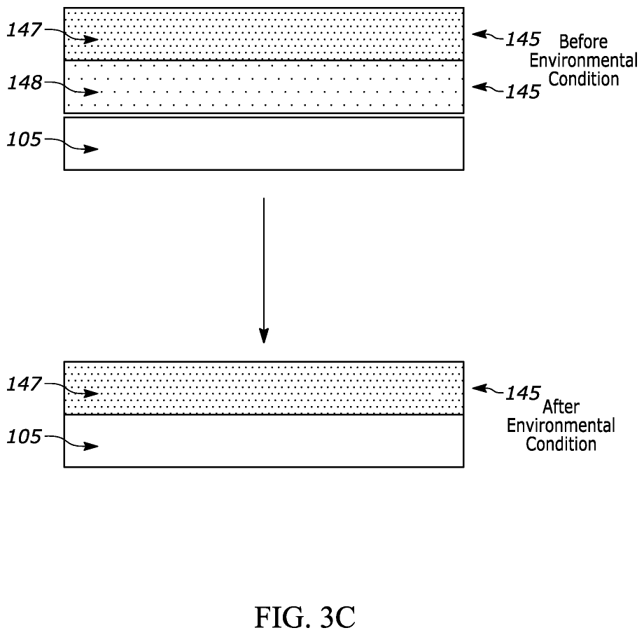

As another example, a conductive material can be disposed in proximity to the area defined by the multi-path loop component 105, where the conductive material is physically separated and/or electrically isolated from the discontinuous conductive paths, e.g., as described in more detail with reference to FIGS. 3A-C. In response to a predetermined environmental condition, such as at least one of a temperature that satisfies a temperature threshold, a humidity that satisfies a humidity threshold, a pressure that satisfies a pressure threshold, a mechanical property that satisfies a mechanical property threshold, exposure to a specified level of chemical, or light that satisfies an illumination threshold, the conductive material can migrate and come in physical and electrical contact with at least a portion of the area such that the conductive material can complete at least one of the discontinuous conductive paths to form a continuous circuit between the terminal ends of the multi-path loop component 105, which can be detected by the logic circuit 130. In response to determining that a continuous circuit path has been formed, the logic circuit 130 may output a signal.

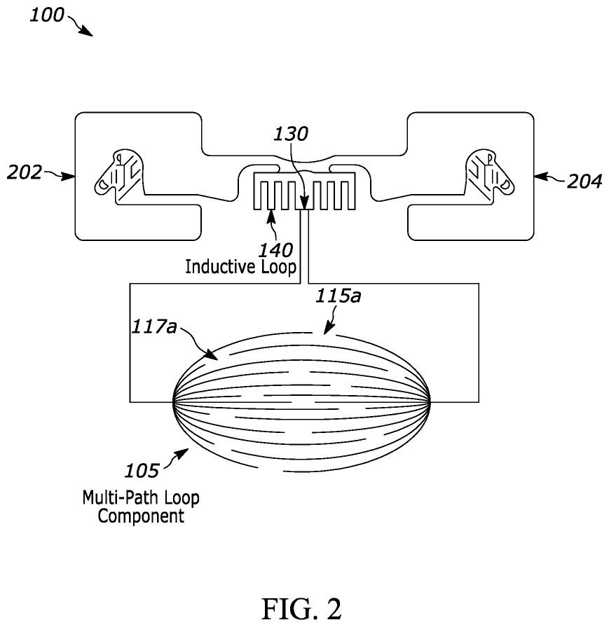

The system may also comprise at least one antenna 125. The logic circuit 130 may be configured to transmit a signal, which indicates the formation of a continuous circuit path has been detected, to the antenna such that the antenna radiates the signal as a radiofrequency signal, for example, to a remote device (e.g., a radiofrequency communication device). The system can be a passive system. For example, the logic circuit 130 and antenna 125 can be a passive radiofrequency identification device (RFID) tag, as described in more detail with reference to FIG. 2. A RFID reader can transmit a radiofrequency interrogation signal, which can be received by the antenna and converted to an electrical current which can power the logic circuit 130, which can allow the logic circuit 130 to determine a status of the multi-path loop component and can transmit the signal indicating the status back to the RFID reader. Alternatively, or in addition, the system may optionally include a battery 135 to power the logic circuit 130. For example, the system 100 powered by battery 135 may be configured to transmit the signal without needing an interrogation signal from an RFID reader. In one example, when the system is powered by the battery 135, the system can be configured to perform Bluetooth beaconing, in which, in response to the logic circuit 130 detecting the formation of a continuous circuit path in the multi-path loop component 105, the logic circuit 130 begins to periodically output a signal indicating the formation of a continuous circuit path in the multi-path loop component 105.

In another example, the multi-path loop component may be configured to include a plurality of discontinuous conductive paths that are completed with a conductive material which bridges or completes the discontinuities of the discontinuous conductive paths to form a continuous circuit between the terminal ends of the multi-path loop component 105. In response to at least one environmental condition, conductive material can be wicked away or separated from the plurality of discontinuous conductive paths to generate the discontinuities in the discontinuous conductive paths to form an discontinuous circuit between the terminal ends of the multi-path loop component 105. The logic circuit 130 may be configured to output a signal indicating the disconnection of a complete circuit path.

FIG. 1C illustrates another example system of the present disclosure. The system 100 may include a multi-path loop component 105, having at least one of the plurality of interleaved discontinuous conductive paths of the multi-path loop component 105 with at least two discontinuities, e.g. path 110a and discontinuities 115a and 115b. As shown in FIG. 1C, in the multi-path loop component 105, each of the plurality of interleaved discontinuous conductive paths comprises at least two discontinuities.

FIG. 2 illustrates an example system 100 of the present disclosure in which the system 100 is an RFID tag. For example, the system 100 may be a RFID tag. As shown in FIG. 2, the RFID tag include the logic circuit 130, an inductive loop 140, and antennas 125, where the logic circuit is coupled to the inductive loop 140 and operatively coupled to the antennas 125 via the inductive loop 140. The inductive loop itself can function as an antenna (and the RFID tag can be devoid of far-field antennas 125), for example, in near-field applications. One terminal end of the multi-path loop 105 is electrically connected to a first contact or node of the logic circuit 130 and the other terminal end of the multi-path loop component 105 is electrically connected to a second contact or node of the logic circuit 130.

The RFID tag can be readable as described herein by a corresponding radiofrequency device, such as an RFID reader/interrogator. The RFID tag can be an ultra-high frequency (UHF) RFID circuit configured for far-field radiofrequency communication (e.g., in a frequency range of approximately 860 MHz to approximately 960 MHz). As a non-limiting example, the RFID tag can be configured according to one or more proprietary schemes and/or according to one or more standards, such as ISO 18000-6A, ISO 18000-6B, ISO 18000-6C, ISO/IEC 29143, and/or other standards. The logic circuit 130 can be operative to respond to a far-field radiofrequency communication via the inductive loop 140 and antennas 125. The RFID tag can be a passive RFID tag and the inductive loop 140 can power the logic circuit 130 via inductive coupling in response to radiofrequency waves, e.g., emitted by an RFID reader/interrogator, which induces an electric current in the antennas 125 and the inductive loop 140.

As described herein, one or more of the discontinuous conductive paths can be completed by a conductive material coming in physical and electrical contact with the one or more discontinuous conductive paths to form a continuous circuit between the first and second contact/nodes of the logic circuit 130 in response to an environmental condition. Alternatively, the discontinuous conductive paths can be completed by the conductive material until an environmental condition occurs, at which time, conductive material can be moved away from the discontinuities in the discontinuous conductive paths to form a discontinuous circuit between the first and second contact/nodes of the logic circuit 130. In response to receiving an interrogation signal from an RFID reader, the logic circuit 130 can be powered by the inductive coupling and make a determination whether a continuous circuit path is formed between the first and second contacts/nodes (or a discontinuous circuit path is formed in some embodiments) and transmit the signal indicating a status of the circuit path. For example, in response to a reader providing RF energy to the system 100 (i.e. reading the RFID tag), the logic circuit 130, if it determines the formation of a complete circuit path, outputs a signal indicating such formation to the antenna 125 for transmission to the reader or a remote host. Accordingly, the logic circuit 130 is configured to output the signal via the antenna in response to receipt of a radiofrequency communication via the antenna after detecting that the continuous circuit path has been formed.

Alternatively, the system 100 may be an active RFID tag, automatically outputting the signal indicating a continuous circuit path has been formed (e.g. due to an environmental condition and filling a discontinuity 115a in at least one of the plurality of discontinuous conductive paths with a conductive material) via antenna 125, in response to a detection of a continuous circuit path by the logic circuit 130.

The logic circuit 130 may be configured to detect the formation of multiple continuous conductive paths in the plurality of interleaved discontinuous conductive paths, and can be configured to output the signal after the multiple continuous conductive paths are formed. For example, conductive material may form continuous conductive paths by completing discontinuities 115a and 117a. In another embodiment, the logic circuit 130 may not transmit the signal indicating a complete circuit path unless a continuous circuit path is formed from each discontinuity of the plurality of interleaved discontinuous conductive paths of the multi-path loop component 105.

FIGS. 3A-C illustrate another example system of the present disclosure. The system 100 may include a reactive component 145, which may be disposed over the multi-path loop component. The reactive component 145 may include a conductive material 147 which is disposed proximate to the area defined by the plurality of interleaved discontinuous conductive paths. The reactive component 145 may be configured to react to at least one environmental condition, which causes the conductive material 147 of the reactive component 145 to physically and electrically contact at least a portion of the area to form the continuous circuit path at least one of during or after the at least one environmental condition. For example, the reactive component 145 may include a meltable component 148 that separates the conductive material 147 from the plurality of interleaved discontinuous conductive paths of the multi-path loop component 105. The meltable component 148 may be configured to melt in response to the at least one environmental condition (e.g. temperature exceeding a temperature threshold) such that the conductive material 147 comes into contact with at least a portion of the area defined by the plurality of interleaved discontinuous conductive paths of the multi-path loop component 105 to form a continuous circuit path.

The at least one environmental condition may include, e.g., at least one of a temperature that satisfies a temperature threshold, a humidity that satisfies a humidity threshold, a pressure that satisfies a pressure threshold, a mechanical property that satisfies a mechanical property threshold, exposure to a specified level of chemical, or light that satisfies an illumination threshold. As one example, when exposed to environment condition exceeds the threshold (e.g., a pressure that exceeds a pressure threshold), the portions of the reactive component 145 separating the conductive material 147 from the multi-path loop component 105 may be configured to break or deform causing the conductive material 147 to come into contact with at least a portion of the area defined by the plurality of interleaved discontinuous conductive paths to form a continuous circuit path, e.g. by conductive material 147 connecting discontinuity 115a. The logic circuit 130 may, in response to receiving a signal from a reader via antenna 125, transmit a signal via antenna 125 indicating that a continuous circuit path has been formed in the multi-path loop component 105 in response to at least one environmental condition.

As another example, the system 100 may include the multi-path loop component 105 being positioned on or proximate to an engine. The system 100 may include a reactive component 145 which includes conductive material 147 separated from the multi-path loop component 105. In response to the temperature of the engine exceeding a predetermined temperature threshold, the reactive component 145 may be configured to melt such that the conductive material comes into contact with at least a portion of the area defined by the plurality of interleaved discontinuous conductive paths to form a continuous circuit path. The logic circuit 130 may detect this formation and transmit a signal via antenna 125 to a controller (not depicted) operatively coupled to the engine. The controller may in response transmit a control signal to the engine that adjusts the operation of the engine (e.g. shuts off the engine).

In another example, a multi-path loop component 105 may be located proximate to a motor to be monitored for leakage. The system 100 may include a reactive component 145 which includes conductive material 147 separated from the multi-path loop component 105. In response to at least one environmental condition, the motor may begin to leak oil onto the area of the multi-path loop component 105 defined by the plurality of interleaved discontinuous conductive paths. The reactive component 145 may be configured to dissolve or melt as a result of coming into contact with oil. As a result, the conductive material may form a continuous circuit path, which is detected by the logic circuit 130. The logic circuit 130 then may transmit a signal indicating the formation of a continuous circuit path, which corresponds to the detection of a leaking motor, which may then be addressed by either the controller adjusting the operation of the motor or by dispatching service technicians to the location.

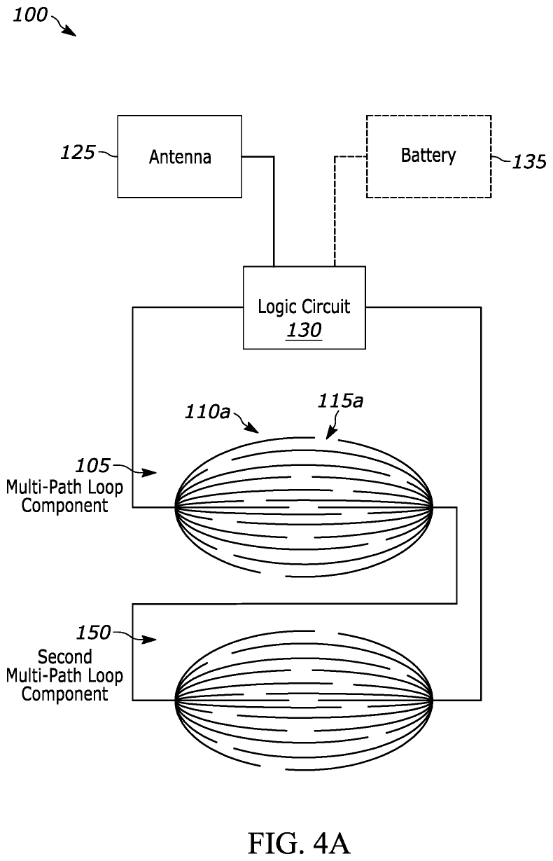

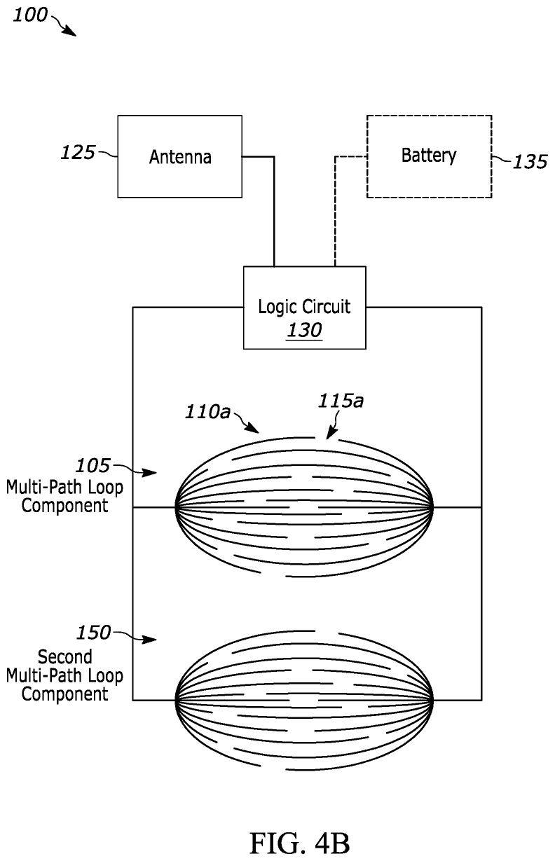

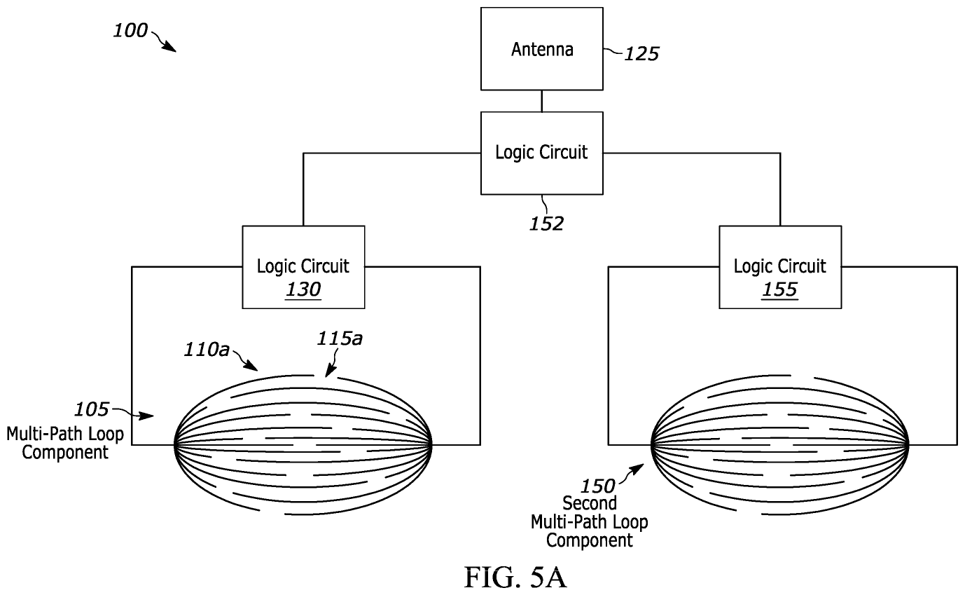

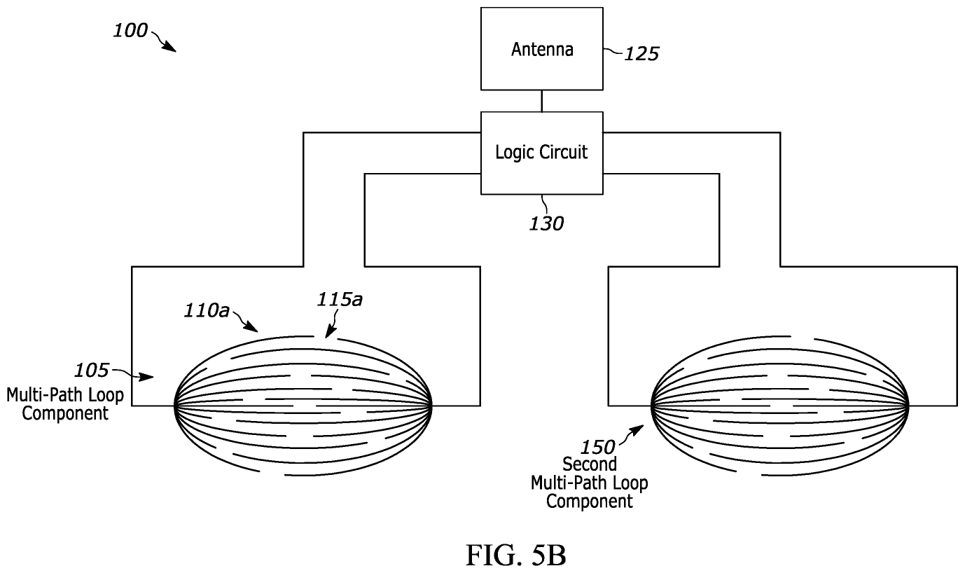

FIGS. 4A-B and 5A-B illustrate additional example systems of the present disclosure. FIGS. 4A-B illustrate a system 100 which includes a second multi-path loop component 150. The second multi-path loop component 150 may be operatively coupled to the logic circuit 130 and may be connected either in series (FIG. 4A) or in parallel (FIG. 4B) with the multi-path loop component 105. FIG. 5B illustrates a system 100 which includes a second multi-path loop component 150 operatively connected to a second logic circuit 155, where logic circuits 130 and 155 are operatively coupled to a logic circuit 152 that can process signals indicative of whether their respect multi-path loop components 105 and 150 form continuous or discontinuous circuits from the logic circuits 130 and 155. The logic circuit 152 can output one or more signals via the antennas based on the signals received from the logic circuits 130 and 155 to indicate the status of the multi-path loop components 105 and/or 150. FIG. 5B illustrates a system in which the logic circuit includes a pair of contacts/node for connecting the multi-path loop component 105 and a second pair of contacts/node for connecting the multi-path loop 150, where the logic circuit 130 can independently determine whether the multi-path loop component 105 and/or the multi-path loop component 150 form continuous or discontinuous circuits.

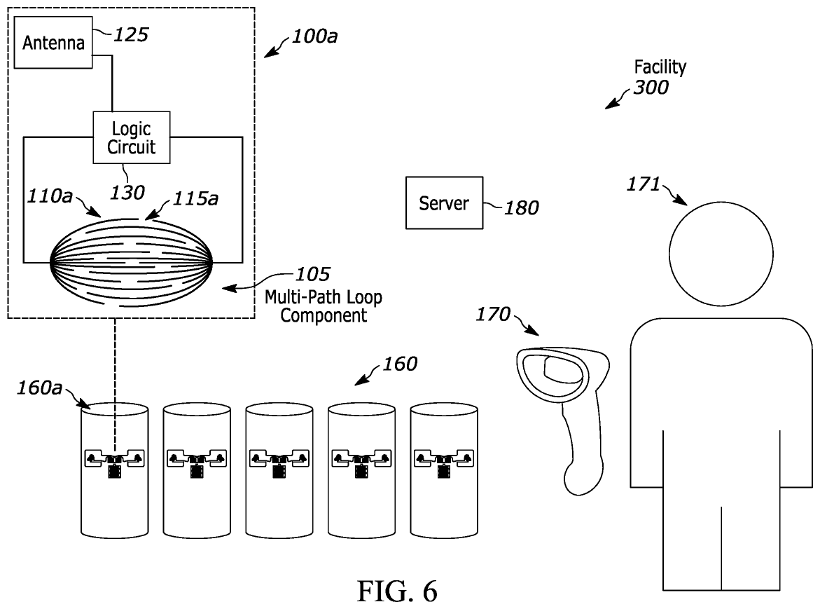

FIG. 6 illustrates another example system of the present disclosure. A facility 300 may house a fleet of objects 160, each object, e.g. object 160a, each having a system 100a of the present disclosure affixed to it. Each system may include a multi-path loop component 105 having a plurality of interleaved discontinuous conductive paths, and a logic circuit 130 configured to detect the formation of a continuous circuit path in the multi-path loop component 105 in response to an environmental condition. A user 171 may periodically take inventory of the fleet 160 of objects which may include using a transceiver 170 which sends a signal to the antenna 125 of one of the objects, e.g. 160a, which, in response to receiving this signal, the logic circuit 130 determines whether a complete circuit path has been formed in the multi-path loop component 105 in response to an environmental condition. In response to detecting the formation of a completed circuit path, the logic circuit 130 may transmit a signal via antenna 125 to a server 180, remote from the transceiver 170, which may store data received from the system 100a. In response to receiving such a signal from the logic circuit 130, server 180 may alert the user that an environmental condition has caused the formation of a completed circuit path. Alternatively, or in addition, the facility 300 can include fixed RFID readers that can periodically poll (e.g., transmit an RF interrogation signal) the systems 100a to determine a status of the multi-path loop components 130).

For example, facility 300 may be a warehouse storing a fleet of batteries, whose health needs to be monitored in inventoried to reduce the risk of batteries being placed into service that are not in working order. A user 171 may periodically take inventory of the health of the batteries in the battery storage facility. For each battery, an RFID reader, e.g transceiver 170, may automatically interrogate or may be controlled by the user 171 to interrogate the health of the battery by reading the system affixed to the battery (e.g. system 100a affixed to object 160a). The antenna 125 receives the signal from the reader 170, and in response, the logic circuit 130 transmits a signal via antenna 125 indicating that a completed circuit path has formed in the multi-path loop component 105 to a server 180. Such an indication corresponds to a leak detected in the battery, meaning that the battery is unreliable and should not be used. The server may include the necessary circuitry to track such status of each battery in the battery storage facility 300. The response from the systems 100a can also be used to determine a location of systems 100a in the facility 300 for which the multi-path loop components indicate a damaged or abnormal operation of the battery.

Other example facilities may include storage facilities for perishable items, such as food items or pharmaceuticals, and non-perishable items, such as canned goods or electronics, in which the items are monitored, each having a system, e.g. system 100a, affixed thereto, to detect whether an environmental condition, for example, a temperature threshold or a humidity threshold being exceeded, has resulted in the formation of a completed circuit path in the multi-path loop component 105.

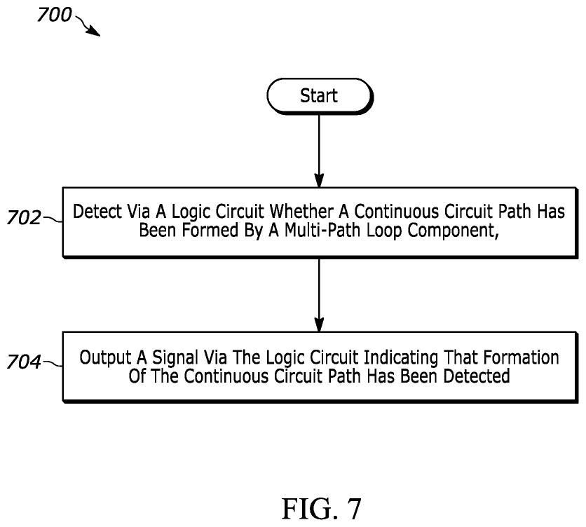

FIG. 7 is a block flowchart illustrating a method of the present disclosure. Although the example method 700 is described with reference to the flowchart illustrated in FIG. 7, it will be appreciated that many other methods of performing the acts associated with the method 700 may be used. For example, the order of some of the blocks may be changed, certain blocks may be combined with other blocks, blocks may be repeated, and some of the blocks described are optional. The method 400 may be performed by processing logic that may comprise hardware (circuitry, dedicated logic, etc.), software, or a combination of both.

Method 700 includes, in response to at least one environmental condition, detecting via a logic circuit whether a continuous circuit path has been formed by a multi-path loop component, the multi-path loop component including a plurality of interleaved discontinuous conductive paths, each having at least one discontinuity, the plurality of interleaved discontinuous conductive paths forming a parallel circuit component, wherein the logic circuit is operatively coupled to the multi-path loop component (block 702). For example, a multi-path loop component 105 may be located proximate to a battery to be monitored for leakage, such that if the battery is experiencing leakage, it would leak conductive material at least in part onto the area defined by the plurality of interleaved discontinuous conductive paths.

Also, method 700 further includes outputting a signal via the logic circuit 130 indicating that formation of the continuous circuit path has been detected (block 704). For example, in the event the monitored battery leaks conductive material to form a continuous circuit path in the multi-path loop component 105.

The above description refers to a block diagram of the accompanying drawings. Alternative implementations of the example represented by the block diagram include one or more additional or alternative elements, processes and/or devices. Additionally or alternatively, one or more of the example blocks of the diagram may be combined, divided, re-arranged or omitted. Components represented by the blocks of the diagram are implemented by hardware, software, firmware, and/or any combination of hardware, software and/or firmware. In some examples, at least one of the components represented by the blocks is implemented by a logic circuit. As used herein, the term “logic circuit” is expressly defined as a physical device including at least one hardware component configured (e.g., via operation in accordance with a predetermined configuration and/or via execution of stored machine-readable instructions) to control one or more machines and/or perform operations of one or more machines. Examples of a logic circuit include one or more processors, one or more coprocessors, one or more microprocessors, one or more controllers, one or more digital signal processors (DSPs), one or more application specific integrated circuits (ASICs), one or more field programmable gate arrays (FPGAs), one or more microcontroller units (MCUs), one or more hardware accelerators, one or more special-purpose computer chips, and one or more system-on-a-chip (SoC) devices. Some example logic circuits, such as ASICs or FPGAs, are specifically configured hardware for performing operations (e.g., one or more of the operations described herein and represented by the flowcharts of this disclosure, if such are present). Some example logic circuits are hardware that executes machine-readable instructions to perform operations (e.g., one or more of the operations described herein and represented by the flowcharts of this disclosure, if such are present). Some example logic circuits include a combination of specifically configured hardware and hardware that executes machine-readable instructions. The above description refers to various operations described herein and flowcharts that may be appended hereto to illustrate the flow of those operations. Any such flowcharts are representative of example methods disclosed herein. In some examples, the methods represented by the flowcharts implement the apparatus represented by the block diagrams. Alternative implementations of example methods disclosed herein may include additional or alternative operations. Further, operations of alternative implementations of the methods disclosed herein may combined, divided, re-arranged or omitted. In some examples, the operations described herein are implemented by machine-readable instructions (e.g., software and/or firmware) stored on a medium (e.g., a tangible machine-readable medium) for execution by one or more logic circuits (e.g., processor(s)). In some examples, the operations described herein are implemented by one or more configurations of one or more specifically designed logic circuits (e.g., ASIC(s)). In some examples the operations described herein are implemented by a combination of specifically designed logic circuit(s) and machine-readable instructions stored on a medium (e.g., a tangible machine-readable medium) for execution by logic circuit(s).

In the foregoing specification, specific embodiments have been described. However, one of ordinary skill in the art appreciates that various modifications and changes can be made without departing from the scope of the disclosure as set forth in the claims below. Accordingly, the specification and figures are to be regarded in an illustrative rather than a restrictive sense, and all such modifications are intended to be included within the scope of present teachings. Additionally, the described embodiments/examples/implementations should not be interpreted as mutually exclusive, and should instead be understood as potentially combinable if such combinations are permissive in any way. In other words, any feature disclosed in any of the aforementioned embodiments/examples/implementations may be included in any of the other aforementioned embodiments/examples/implementations.

The benefits, advantages, solutions to problems, and any element(s) that may cause any benefit, advantage, or solution to occur or become more pronounced are not to be construed as a critical, required, or essential features or elements of any or all the claims. The claimed disclosure is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus, the following claims are hereby incorporated into the Detailed Description, with each claim standing on its own as a separately claimed subject matter.

1. A system comprising:
a multi-path loop component, the multi-path loop component including a plurality of interleaved discontinuous conductive paths that form a parallel circuit component; and
a logic circuit operatively coupled to the multi-path loop component,
the logic circuit configured to detect whether a continuous circuit path has been formed by at least one of the plurality of interleaved discontinuous conductive paths in response to at least one environmental condition in an area defined by the plurality of interleaved discontinuous conductive paths, and
the logic circuit configured to output a signal that indicates that formation of the continuous circuit path has been detected.

2. The system of claim 1, further comprising:
an antenna,
wherein the logic circuit is configured to output the signal via the antenna in response to detecting that the continuous circuit path has been formed.

3. The system of claim 1, further comprising:
an antenna,
wherein the logic circuit is configured to output the signal via the antenna in response to receipt of a radiofrequency communication via the antenna after detecting that the continuous circuit path has been formed.

4. (canceled)

5. The system of claim 1, wherein discontinuities of adjacent ones of the plurality of interleaved discontinuous paths are at least partially offset from each other.

6. The system of claim 1, further comprising:
a substrate,
wherein the multi-path loop component is formed from at least one metallic etching etched into the substrate or transfer of an electrically conductive ink onto the substrate.

7. The system of claim 1, further comprising:
a reactive component that reacts to the at least one environmental condition, the reactive component including a conductive material disposed proximate to the area defined by the plurality of interleaved discontinuous conductive paths,
the conductive material being spaced away from the plurality of interleaved discontinuous conductive paths prior to the at least one environment condition, and
the reactive component reacting to the at least one environment condition to cause the conductive material to contact at least a portion of the area to form the continuous circuit path at least one of during or after the at least one environmental condition.

8. The system of claim 7, wherein the reactive component includes a meltable component that separates the conductive material from the plurality of interleaved discontinuous conductive paths, and the meltable component melts in response to the at least one environment condition.

9. The system of claim 7, wherein the at least one environmental condition includes at least one of a temperature that satisfies a temperature threshold, a humidity that satisfies a humidity threshold, a pressure that satisfies a pressure threshold, a mechanical property that satisfies a mechanical property threshold, exposure to a specified level of a chemical, or light that satisfies an illumination threshold.

10. The system of claim 1, wherein the environmental condition corresponds to the deposition of a conductive material onto the area of the plurality of interleaved discontinuous conductive paths in response to damage to or abnormal operation of an object being monitored by the logic circuit.

11. (canceled)

12. The system of claim 1, wherein at least one of the plurality of interleaved discontinuous conductive paths has at least two discontinuities.

13. The system of claim 1, wherein the logic circuit is further configured to detect formation of multiple continuous conductive paths in the plurality of interleaved discontinuous conductive paths, and is configured to output the signal after the multiple continuous conductive paths are formed.

14. The system of claim 1, wherein the logic circuit is configured to output the signal after continuous conductive paths are formed for each of the plurality of interleaved discontinuous conductive paths.

15. The system of claim 1, further comprising a second multi-path loop operatively coupled to the logic circuit in parallel or series with the multi-path loop.

16. The system of claim 1, further comprising:
a second multi-path loop component; and
a second logic circuit, the second multi-path loop is operatively coupled to the second logic circuit.

17. A method comprising:
in response to at least one environmental condition, detecting via a logic circuit whether a continuous circuit path has been formed by a multi-path loop component, the multi-path loop component including a plurality of interleaved discontinuous conductive paths, each having at least one discontinuity, the plurality of interleaved discontinuous conductive paths forming a parallel circuit component, wherein the logic circuit is operatively coupled to the multi-path loop component, and
outputting a signal via the logic circuit indicating that formation of the continuous circuit path has been detected.

18. The method of claim 17, further comprising transmitting the output signal via an antenna.

19. The method of claim 17, further comprising transmitting the output signal via an antenna, in response to receiving a radiofrequency communication via the antenna.

20. (canceled)

21. (canceled)

22. The method of claim 17, wherein the multi-path loop component is formed from etching at least one metallic etching into a substrate or by transferring electrically conductive ink onto a substrate.

23. The method of claim 17, wherein detecting whether a continuous circuit path has been formed includes determining whether a reactive component has reacted to at least one environmental condition, the reactive component including a conductive material disposed proximate to the area defined by the plurality of interleaved discontinuous conductive paths, and the conductive material being spaced away from the plurality of interleaved discontinuous conductive paths prior to the at least one environment condition, wherein the at least one environmental condition causes the conductive material to contact at least a portion of the area to form the continuous circuit path at least one of during or after the at least one environmental condition.

24. The method of claim 23, wherein the reactive component includes a meltable component that separates the conductive material from the plurality of interleaved discontinuous conductive paths, and the meltable component melts in response to the at least one environment condition.

25. The method of claim 23, wherein the at least one environmental condition includes at least one of a temperature that satisfies a temperature threshold, a humidity that satisfies a humidity threshold, a pressure that satisfies a pressure threshold, a mechanical property that satisfies a mechanical property threshold, exposure to a specified level of chemical, or light that satisfies an illumination threshold.

26. (canceled)

27. (canceled)

28. (canceled)

29. (canceled)

30. (canceled)

31. (canceled)

32. (canceled)

33. (canceled)
